(19) United States
(12) Patent Application Publication
(10) Pub. No.: US 2010/0140646 A1
(43) Pub. Date: Jun. 10, 2010

(54) SEMICONDUCTOR LIGHT EMITTING DIODE

(75) Inventor: Il-Kweon JOUNG, Seongnam-si (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/634,101

(22) Filed: Dec. 9, 2009

(30) Foreign Application Priority Data
Dec. 9, 2008 (KR) 10-2008-0124901

(51) Int. Cl. H01L 33/00

(52) U.S. Cl. 257/98; 257/E33.005; 257/E33.064

(57) ABSTRACT

A semiconductor LED is disclosed. The semiconductor LED can include a light emitting structure, which can be composed of an N-type semiconductor layer, an active layer, and a P-type semiconductor layer stacked in said order; a transparent electrode, formed on an upper surface of the light emitting structure; and a P-type electrode, formed on an upper surface of the transparent electrode. An insulator for blocking electric currents can be formed within the light emitting structure, at a position corresponding with the position of the P-type electrode. Certain embodiments of the invention can be used to prevent the occurrences of light reflecting off the lower surface of the P-type electrode, and thereby improve light-emitting efficiency.

### CROSS-REFERENCE TO RELATED APPLICATIONS

This application claims the benefit of Korean Patent Application No. 10-2008-0124901, filed with the Korean Intellectual Property Office on Dec. 9, 2008, the disclosure of which is incorporated herein by reference in its entirety.

### BACKGROUND

1. Technical Field

The present invention relates to a semiconductor light emitting diode.

2. Description of the Related Art

Nitrides of group-III elements, such as gallium nitride (GaN), aluminum nitride (AlN), etc., exhibit high thermal stability and provide a direct transition type energy band structure, and are hence commonly used as materials in photoelectric elements for blue and ultraviolet light. In particular, blue and green light emitting diodes (LEDs) that use gallium nitride (GaN) are utilized in a variety of applications, examples of which include large flat panel displays, traffic lights, indoor lighting, high-density light sources, high-resolution output systems, and optical communication.

The arrangement of a nitride semiconductor LED may include a substrate, a buffer layer, a P-type semiconductor layer, an active layer, an N-type semiconductor layer, and electrodes. The active layer, where the recombination of electrons and electron holes may occur, can include quantum well layers, expressed by the formula InₓGa₁₋ₓN (0≦x≦1), and quantum barrier layers. The wavelength of the light emitted from the LED may be determined by the type of material forming the active layer.

A brief description of a semiconductor LED based on the related art is provided as follows, with reference to FIGS. 1 and 2, which illustrate a semiconductor light emitting diode based on the related art.

As depicted in FIGS. 1 and 2, a semiconductor LED according to the related art may be composed of a sapphire substrate 10, for growing a GaN-based semiconductor material, as well as an N-type semiconductor layer 20, an active layer 40, and a P-type semiconductor layer 50, which are formed in the said order on the sapphire substrate 10. Portions of the P-type semiconductor layer 50 and active layer 40 may be removed, for example, by using a mesa etching process, to form a structure exposing portions of the upper surface of the N-type semiconductor layer 20.

A transparent electrode 60 and a P-type electrode 70 may be formed on the P-type semiconductor layer 50, while an N-type electrode 30 may be formed on the N-type semiconductor layer 20 exposed through the mesa etching process.

When electrical power is supplied to a semiconductor LED having this arrangement, an electric current may flow between the P-type electrode 70 and the N-type electrode 30, as illustrated in FIG. 1, and accordingly, the active layer 40 may produce light. The arrows in FIG. 1 represent the flow of electric currents.

Such a flow of electric currents can result in light emission from the active layer 40. Here, the light emitted from a portion of the active layer underneath the P-type electrode 70 may be blocked by the P-type electrode 70, as illustrated in FIG. 2, to be reflected and absorbed inside the semiconductor LED. As such, this portion of light may not be emitted to the outside, and consequently, the light-emitting efficiency of the semiconductor LED may be lowered.

### SUMMARY

Certain aspects of the invention provide a semiconductor light emitting diode having improved light-emitting efficiency.

One aspect of the invention provides a semiconductor light emitting diode that includes: a light emitting structure, which can be composed of an N-type semiconductor layer, an active layer, and a P-type semiconductor layer stacked in said order; a transparent electrode, formed on an upper surface of the light emitting structure; and a P-type electrode, formed on an upper surface of the transparent electrode. An insulator for blocking electric currents can be formed within the light emitting structure, at a position corresponding with the position of the P-type electrode.

The insulator can be formed in such a way that the insulator penetrates through the light emitting structure. The shape of the light emitting structure may be such that has a portion removed by mesa etching, starting from the P-type semiconductor layer and ending at a point within the N-type semiconductor layer.

In certain embodiments, the width of the insulator may be the same as that of the P-type electrode.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 and FIG. 2 are cross-sectional views illustrating a semiconductor light emitting diode based on the related art.

FIG. 3 and FIG. 4 are cross-sectional views illustrating a semiconductor light emitting diode based on an embodiment of the invention.

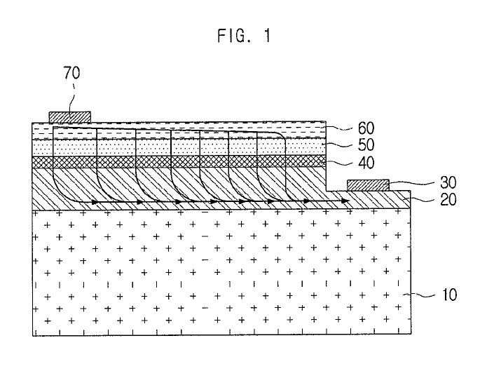

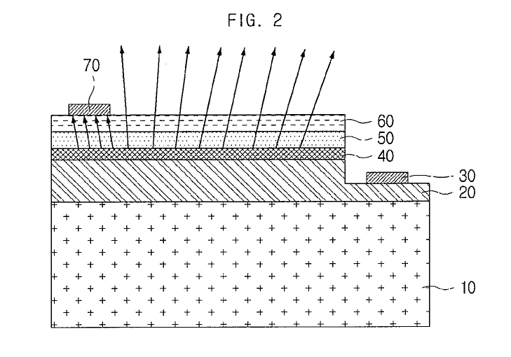

### DETAILED DESCRIPTION

As the invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention.

The semiconductor light emitting diode according to certain embodiments of the invention will be described below in more detail with reference to the accompanying drawings. Those elements that are the same or are in correspondence are rendered the same reference numeral regardless of the figure number, and redundant descriptions are omitted.

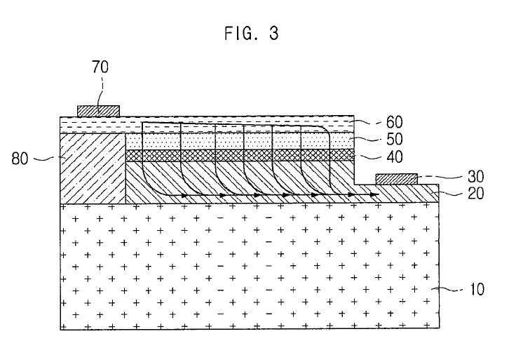

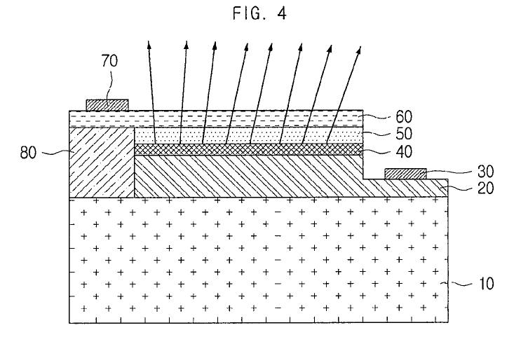

FIG. 3 and FIG. 4 are cross-sectional views illustrating a semiconductor light emitting diode based on an embodiment of the invention. Illustrated in FIGS. 3 and 4 are a substrate 10, an N-type semiconductor layer 20, an N-type electrode 30, an active layer 40, a P-type semiconductor layer 50, a transparent electrode 60, a P-type electrode 70, and an insulator 80.

As illustrated in FIGS. 3 and 4, a nitride semiconductor LED based on an embodiment of the invention may include a substrate 10, and a buffer layer, an N-type semiconductor layer 20, an active layer 40, and a P-type semiconductor layer 50, which are formed in the said order on the substrate 10. Portions of the P-type semiconductor layer 50 and active layer 40 can be removed, using a mesa etching process to form an arrangement exposing a portion of the upper surface of the N-type semiconductor layer 20.

An N-type electrode 30 can be formed on the exposed portion of the N-type semiconductor layer 20. Also, a transparent electrode 60 made of ITO (indium-tin oxide), etc., can be formed on the P-type semiconductor layer 50, and a P-type electrode 70 can be formed on the transparent electrode 60.

The substrate 10 can be made from a material suitable for growing nitride semiconductor monocrystals. For example, the substrate 10 may be formed using a material such as sapphire, as well as zinc oxide (ZnO), gallium nitride (GaN), silicon carbide (SiC), aluminum nitride (AlN), etc.

While it is not illustrated in the drawings, a buffer layer can also be formed on the upper surface of the substrate 10, to reduce the difference in lattice constants between the substrate 10 and the N-type semiconductor layer 20, which will be described later in greater detail. The buffer layer (not shown) can be made from a material such as GaN, AlN, AlGaN, InGaN, AlGaInN, etc., or can be omitted depending on the properties of the diode and the conditions for processing.

The N-type semiconductor layer 20 can be formed on the upper surface of the substrate 10 (or the buffer layer). The N-type semiconductor layer 20 can be made from a gallium nitride (GaN)-based material, and can be doped with silicon to lower the operating voltage.

The active layer 40, which may include a quantum well layer (not shown) and a quantum barrier layer (not shown), can be formed on the N-type semiconductor layer 20. The numbers of quantum well layers and quantum barrier layers, which implement a quantum well structure, may vary according to design requirements.

The P-type semiconductor layer 50 can be formed on the active layer 40. The P-type semiconductor layer 50 may be a semiconductor layer doped with P-type conductive impurities, such as Mg, Zn, Be, etc. The P-type semiconductor layer 50 may also be composed of a P-type AlGaN layer (not shown), formed adjacent to the light-emitting region to serve as an electron-blocking layer (EBL), and a P-type GaN layer (not shown), formed adjacent to the P-type AlGaN layer.

In this disclosure, the N-type semiconductor layer 20, active layer 40, and P-type semiconductor layer 50 will be referred to collectively as a light emitting structure. Such a light emitting structure can be formed by growing the N-type semiconductor layer 20, active layer 40, and P-type semiconductor layer 50 in the said order on the substrate 10 (or buffer layer).

A transparent electrode 60 can be formed on the P-type semiconductor layer 50. The transparent electrode 60 can be a transmissive layer of an oxide membrane and can be made from ITO, ZnO, RuOₓ, TiOₓ, IrOₓ, etc.

A certain portion between the transparent electrode 60 and the N-type semiconductor layer, inclusive, can be removed by mesa etching, and the N-type electrode 30 can be formed on a part of the N-type semiconductor layer 20 exposed by the mesa etching and the P-type electrode 70 can be formed on the transparent electrode 60.

According to this particular embodiment, an insulator 80 can be formed inside the light emitting structure, at a position corresponding with that of the P-type electrode 70, as illustrated in FIG. 3. That is, an insulator 80 having substantially the same pattern as that of the P-type electrode 70 can be formed in the light emitting structure positioned under the P-type electrode 70, in such a manner that the insulator 80 penetrates through the light emitting structure.

This arrangement may be obtained, for example, using a method of forming the light emitting structure, preparing the required space inside the light emitting structure by etching the light emitting structure, in consideration of the position where the P-type electrode 70 is to be formed, and then filling an insulating material into the prepared space.

Afterwards, by forming a transparent electrode 60 on an upper surface of the light emitting structure and forming a P-type electrode 70 on the transparent electrode 60, the desired arrangement may be obtained in which the insulator 80 is located below the P-type electrode 70.

When electrical power is supplied between the P-type electrode 70 and the N-type electrode 30 of a semiconductor LED having this arrangement, an electric current may flow as illustrated in FIG. 3. The arrows in FIG. 3 represent the flow of electric currents.

Because of the insulator 80 positioned under the P-type electrode 70, electric currents may not flow directly below the P-type electrode but disperse laterally through the entire transparent electrode 60. Then, as illustrated in FIG. 4, there may not be any portion of the active layer 40 emitting light beneath the P-type electrode 70, and thus there is no light reflected, absorbed, and extinguished by the P-type electrode 70. The arrows in FIG. 4 represent light emitted from the active layer 40.

The electric currents that would have flowed directly under the P-type electrode 70 may instead flow laterally through the transparent electrode 60, towards the regions of the active layer 40 that are not covered by the P-type electrode 70. Therefore, the electric current supplied to the arrangement may be used with minimized loss, and as a result, the light-emitting efficiency of the semiconductor LED may be increased accordingly.

Any material capable of blocking the flow of electric currents below the P-type electrode 70 may be used for the insulator 80. The use of a material such as silicon dioxide (SiO₂), for example, may provide insulation as well as high light transmissivity.

The insulator 80 can be patterned in substantially the same shape as that of the P-type electrode 70. The insulator 80 can be formed inside, and in some cases on the outside of, the light emitting structure. Here, the insulator 80 can be formed with substantially the same width as that of the P-type electrode 70. If the width of the insulator 80 is smaller than the width of the P-type electrode 70, there may still be occurrences of light being reflected and absorbed by portions of the P-type electrode 70. On the other hand, if the width of the insulator 80 is excessively greater than the width of the P-type electrode 70, the area of the active layer 40 actually emitting light may be relatively decreased.

It should be noted, however, that the meaning of the term “same” used herein is not limited to perfect mathematical sameness, but refers instead to substantial sameness, which may include processing tolerances, etc. As such, the width of the insulator 80 may be determined in consideration of processing tolerances, and other design parameters.

While the above descriptions have been provided mainly with regards to a semiconductor LED having an Epi-Up structure, it shall be apparent that the arrangement described above may also be applied to semiconductor LEDs having different structures.

As set forth above, certain embodiments of the invention can be used to prevent the occurrences of light reflecting off the lower surface of the P-type electrode, thereby improving light-emitting efficiency.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

Many embodiments other than those set forth above can be found in the appended claims.

What is claimed is:

1. A semiconductor light emitting diode comprising:
a light emitting structure, the light emitting structure comprising an N-type semiconductor layer, an active layer, and a P-type semiconductor layer stacked in said order;
a transparent electrode formed on an upper surface of the light emitting structure; and
a P-type electrode formed on an upper surface of the transparent electrode,
wherein the light emitting structure has an insulator formed therein at a position corresponding with a position of the P-type electrode, the insulator configured to block an electric current.

2. The semiconductor light emitting diode of claim 1, wherein the insulator penetrates through the light emitting structure.

3. The semiconductor light emitting diode of claim 1, wherein the light emitting structure has a portion thereof removed by mesa etching between the P-type semiconductor layer and a part of the N-type semiconductor layer inclusive.

4. The semiconductor light emitting diode of claim 1, wherein the insulator has a same width as that of the P-type electrode.
